(19) United States
(12) Patent Application Publication
(10) Pub. No.: US 2014/0362064 A1
(43) Pub. Date: Dec. 11, 2014

(54) Active Array Substrate, Driving Method Thereof, and Liquid Crystal Display Panel Using the Same

(71) Applicant: AU OPTRONICS CORP., HSINCHU (TW)

(72) Inventors: Shyh-Bin KUO, HSIN-CHU (TW); Tzu-Wei LIU, HSIN-CHU (TW); Teng-Wei CHEN, HSIN-CHU (TW)

(73) Assignee: AU OPTRONICS CORP., HSINCHU (TW)

(21) Appl. No.: 14/279,535

(22) Filed: May 16, 2014

(30) Foreign Application Priority Data
Jun. 7, 2013 (TW) 102120430
Apr. 23, 2014 (TW) 103114710

(51) Int. Cl. G09G 3/36; H01L 27/12; G02F 1/1362; G02F 1/1343; G02F 1/1335

(52) U.S. Cl. CPC G09G 3/3677; G02F 1/134336; G02F 1/133514; G02F 1/136286; H01L 27/1255; H01L 27/124; G09G 3/3648; G02F 2001/134345; G02F 2001/13629
USPC 345/206; 349/144; 349/108; 257/72

(57) ABSTRACT

The invention discloses an active array substrate, a driving method thereof, and an LCD using the same. The active array substrate includes a substrate, a plurality of first scan lines and second scan lines alternately disposed on the substrate, a plurality of first data lines and second data lines alternately disposed on the substrate, a plurality of first, second, and third sub-pixel electrodes, and a plurality of switches. The plurality of first scan lines and second scan lines intersect the plurality of first data lines and second data lines. Each of the second sub-pixel electrodes and one of the first sub-pixel electrodes are located at opposite sides of one of the second data lines. Each of the third sub-pixel electrodes and one of the first sub-pixel electrodes are located at opposite sides of one of the first data lines.

### RELATED APPLICATIONS

This application claims priority to Taiwan Application Serial Number 102120430, filed Jun. 7, 2013, and Taiwan Application Serial Number 103114710, filed Apr. 23, 2014, which are herein incorporated by reference.

### BACKGROUND

1. Field of Invention

The present invention relates to an active array substrate. More particularly, the present invention relates to an active array substrate used in a liquid crystal display panel.

2. Description of Related Art

With the development of display manufacturing technology, most modern digital display panels have the advantages of light weight, low cost, and high efficiency. Various components (such as the driving circuits, the substrate, and the connection lines) of a digital display panel are highly integrated through various advanced processes so that an optimized display effect can be achieved while realizing a small size and low cost for the digital display panel.

In order to achieve the above-mentioned objectives, many manufacturing technologies for display apparatuses have been developed. In a traditional display panel, a great number of source drivers and gate drivers are disposed to drive the pixels along both the perpendicular and horizontal directions. In the design of a half source driver (HSD), the number of the scan lines is doubled. Hence, a single data line (source line) simultaneously corresponds to two neighboring columns of sub-pixel electrodes to reduce the quantity of the source driver ICs by half. However, in the design of an HSD, the charging efficiencies among individual sub-pixel electrodes are inconsistent and the parasitic capacitances are not balanced to thereby generate line defects along the perpendicular direction.

### SUMMARY

An active array substrate is provided to resolve the line defect problem along the perpendicular direction caused by inconsistent charging efficiencies among individual sub-pixel electrodes and imbalanced capacitances in the traditional design of an HSD.

The active array substrate comprises a substrate, a plurality of first scan lines and a plurality of second scan lines alternately disposed on the substrate, a plurality of first data lines and a plurality of second data lines alternately disposed on the substrate, a plurality of first sub-pixel electrodes, a plurality of second sub-pixel electrodes, a plurality of third sub-pixel electrodes, a plurality of first switches, a plurality of second switches, a plurality of third switches, and a plurality of fourth switches. The first scan lines and the plurality of second scan lines are crossing the plurality of first data lines and the plurality of second data lines. Each of the second sub-pixel electrodes and one of the first sub-pixel electrodes is located at opposite sides of one of the second data lines. Each of the third sub-pixel electrodes is disposed corresponding to one of the first sub-pixel electrodes, and the each of the third sub-pixel electrodes and the corresponding first sub-pixel electrode are located at opposite sides of one of the first data lines. Each of the first switches is connected to one of the first sub-pixel electrodes, one of the first data lines, and one of the first scan lines. Each of the second switches is connected to one of the first sub-pixel electrodes, one of the second data lines, and one of the first scan lines. Each of the third switches is connected to one of the second sub-pixel electrodes, one of the second data lines, and one of the second scan lines. Each of the fourth switches is connected to one of the third sub-pixel electrodes, one of the first data lines, and one of the second scan lines.

The invention provides a liquid crystal display panel. The liquid crystal display panel comprises an active array substrate, an opposite substrate, and a liquid crystal layer disposed between the active array substrate and the opposite substrate. The active array substrate comprises a substrate, a plurality of first scan lines and a plurality of second scan lines alternately disposed on the substrate, a plurality of first data lines and a plurality of second data lines alternately disposed on the substrate, a plurality of first sub-pixel electrodes, a plurality of second sub-pixel electrodes, a plurality of third sub-pixel electrodes, a plurality of first switches, a plurality of second switches, a plurality of third switches, and a plurality of fourth switches. The first scan lines and the plurality of second scan lines are crossing the plurality of first data lines and the plurality of second data lines. Each of the second sub-pixel electrodes and one of the first sub-pixel electrodes is located at opposite sides of one of the second data lines. Each of the third sub-pixel electrodes is disposed corresponding to one of the first sub-pixel electrodes, and the each of the third sub-pixel electrodes and the corresponding first sub-pixel electrode are located at opposite sides of one of the first data lines. Each of the first switches is connected to one of the first sub-pixel electrodes, one of the first data lines, and one of the first scan lines. Each of the second switches is connected to one of the first sub-pixel electrodes, one of the second data lines, and one of the first scan lines. Each of the third switches is connected to one of the second sub-pixel electrodes, one of the second data lines, and one of the second scan lines. Each of the fourth switches is connected to one of the third sub-pixel electrodes, one of the first data lines, and one of the second scan lines.

In summary, the present invention provides a design of the active array substrate to effectively resolve the line defect problem caused by inconsistent charging efficiencies or imbalanced capacitances in the traditional design of an HSD.

It is to be understood that both the foregoing general description and the following detailed description are by examples, and are intended to provide further explanation of the invention as claimed.

### BRIEF DESCRIPTION OF THE DRAWINGS

The invention can be more fully understood by reading the following detailed description of the embodiments, with reference made to the accompanying drawings as follows:

FIG. 1 is a schematic diagram showing a partial top view of an active array substrate according to an embodiment of the present invention;

FIG. 2 is a timing diagram of various signals for driving the active array substrate in FIG. 1;

FIG. 3 is a schematic diagram showing a partial top view of the active array substrate according to another embodiment of the present invention;

FIG. 4 is a schematic diagram showing a cross-sectional view of a liquid crystal panel using the active array substrate according to an embodiment of the present invention; and

FIG. 5 is a schematic diagram showing a partial cross-sectional view of the active array substrate according to a further embodiment of the present to invention.

### DETAILED DESCRIPTION

Reference will now be made in detail to the present embodiments of the invention, examples of which are illustrated in the accompanying drawings. Wherever possible, the same reference numbers are used in the drawings and the description to refer to the same or like parts.

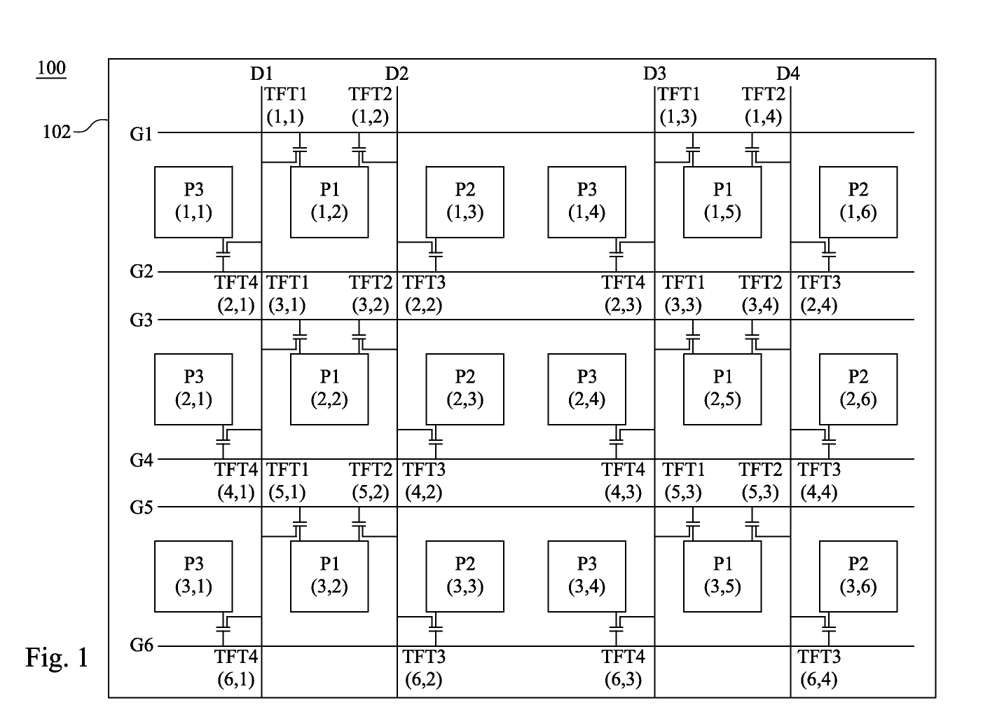

FIG. 1 is a schematic diagram showing a partial top view of an active array substrate according to an embodiment of the present invention. The active array substrate 100 comprises a substrate 102, a plurality of first data lines D1, D3, . . . , a plurality of second data lines D2, D4, . . . ; a plurality of first scan lines G1, G3, G5, . . . , a plurality of second scan lines G2, G4, G6, . . . , and a plurality of sub-pixel electrodes. The second data lines D2, D4, . . . are alternately arranged with the plurality of first data lines D1, D3, . . . , and the second scan lines G2, G4, G6, . . . are alternately arranged with the plurality of first scan lines G1, G3, G5, . . . . The schematic diagram of the partial top view of the active array substrate 100 is used for describing the layout of pixels and driving circuits on the active array substrate 100. The two first data lines D1, D3, the two second data lines D2, D4, the three first scan lines G1, G3, G5, the three second scan lines G2, G4, G6, and the eighteen sub-pixel electrodes (arranged in a 3×6 matrix) are shown by way of example. However, the present invention is not limited to in this regard, and those of ordinary skill in the art may perform modifications and variations to the design as required, and a description in this regard is not provided in the following.

The present invention also provides the active array substrate 100 on which a varied number of sub-pixel electrodes are disposed based on different display resolutions, and a corresponding number of driving circuits (data lines and scan lines) are disposed. Their relative locations, which are similar to those shown in FIG. 1 and which can be realized by repeating the disposition of FIG. 1, are within the scope of the present invention.

In FIG. 1, the plurality of first data lines D1, D3 and the plurality of second data lines D2, D4 are alternately disposed on the substrate 102. The data lines D1, D2, D3, D4 are arranged sequentially. The plurality of first scan lines G1, G3, G5 and the plurality of second scan lines G2, G4, G6 are alternately disposed on the substrate 102. The scan lines G1, G2, G3, G4, G5, G6 are arranged sequentially. The plurality of first data lines D1, D3 and the plurality of second data lines D2, D4 alternately arranged with the plurality of first data lines D1, D3 may be parallel with each other. The plurality of first scan lines G1, G3, G5 and the plurality of second scan lines G2, G4, G6 are alternately arranged, and the scan lines G1, G2, G3, G4, G5, G6 may be parallel with each other. The plurality of first scan lines G1, G3, G5 and the plurality of second scan lines G2, G4, G6 further intersect the plurality of first data lines D1, D3 and the plurality of second data lines D2, D4.

The sub-pixel electrodes includes a plurality of first sub-pixel electrodes P1, a plurality of second sub-pixel electrodes P2, and a plurality of third sub-pixel electrodes P3, in which the first sub-pixel electrode P1, the second sub-pixel electrode P2, and the third sub-pixel electrode P3 are utilized for emitting different colors of light. On the active array substrate 100, the first sub-pixel electrodes P1 are uniformly arranged in a column, the second to sub-pixel electrodes P2 are uniformly arranged in a column, and the third sub-pixel electrodes P3 are uniformly arranged in a column.

To simplify matters, a single column of pixel units (comprising one column of the first sub-pixel electrodes P1, one column of the second sub-pixel electrodes P2, and one column of the third sub-pixel electrodes P3) is used for describing the configuration of the present embodiment. Those of ordinary skill in the art would recognize that the design of the pixel units may be repeated in the active array substrate 100.

The first sub-pixel electrodes P1 and the second sub-pixel electrodes P2 are located on opposite sides of the second data line D2 or D4. The third sub-pixel electrodes P3 and the first sub-pixel electrodes P1 are located on opposite sides of the first data line D1 or D3. The second sub-pixel electrodes P2 and the third sub-pixel electrodes P3 adjacent to the second sub-pixel electrodes P2 are located between the first data line D3 and the second data line D2 adjacent to the first data line D3.

More specifically, each of the sub-pixel electrodes in the sub-pixel electrode matrix is represented by PM(i,j) which denotes the M-th sub-pixel electrode in the ith row and the jth column of the sub-pixel electrode matrix. For example, P3(1,1) in the top left corner of the figure denotes the third sub-pixel electrode P3 in the first row and the first column of the sub-pixel electrode matrix, P2(1,6) in the top right corner of the figure denotes the second sub-pixel electrode P2 in the first row and the sixth column of the sub-pixel electrode matrix, and so forth.

The active array substrate 100 further comprises a plurality of first switches TFT1, a plurality of second switches TFT2, and a plurality of third switches TFT3. In the various embodiments of the present invention, each of the switches is for example a thin film transistor.

Each of the first switches TFT1 is connected to the corresponding first sub-pixel electrode P1, the first data line D1 or D3, and the first scan line G1 or G3 or G5. Each of the second switches TFT2 is connected to the corresponding first sub-pixel electrode P1, the second data line D2 or D4, and the first scan line G1 or G3 or G5. Each of the third switches TFT3 is connected to the corresponding second sub-pixel electrode P2, the second data line D2 or D4, and the second scan line G2 or G4 or G6. Each of the fourth switches TFT4 is connected to the corresponding third sub-pixel electrode P3, the first data lines D1 or D3, and the second scan lines G2 or G4 or G6.

More specifically, the switches can be represented by TFT N (h,k) which denotes the N-th TFT connected to the scan line Gh and the data line Dk. For example, TFT1 (1,1) in the top left corner of the figure denotes the first switch TFT1 connected to the first scan line G1 and the first data line D1, TFT3 (6,4) in the lower right corner of the figure denotes the third switch TFT3 connected to the second scan line G6 and the second data line D4, and so forth.

The first data line D1 is utilized for charging and discharging the first switch TFT1 and the fourth switch TFT4. The second data line D2 is utilized for charging and discharging the second switch TFT2 and the third switch TFT3.

The first scan lines G1, G3, G5 are utilized for switching on the first switch TFT1 and the second switch TFT2. The second scan lines G2, G4, G6 are utilized for switching on the third switch TFT3 and the fourth switch TFT4.

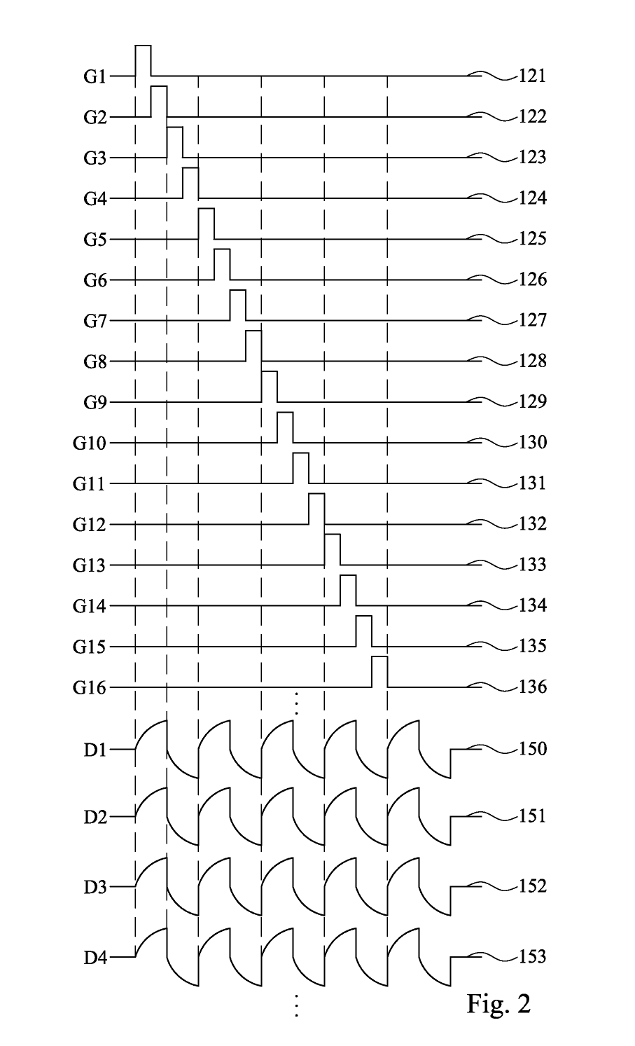

With such a design, the charging time for the first sub-pixel electrode P1, to the second sub-pixel electrode P2, and the third sub-pixel electrode P3 are balanced to resolve the problem of line defects on the screen. Reference is made to the following method for driving the active array substrate 100 shown in FIG. 2 for specific illustration.

FIG. 2 is a timing diagram of various signals for driving the active array substrate 100 in FIG. 1. Referring to both FIG. 1 and FIG. 2, a driving method for the active array substrate 100 comprises providing scan signals 121-136 to the first scan lines and the second scan lines G1-G16 which are alternately arranged sequentially, and providing data signals 150-153 to the first data lines and the second data lines D1˜-D4 which are alternately arranged sequentially. There is no overlap of each of the scan signals 121-136 with other scan signals in the timing sequence. Each of the data signals 150-153 comprises a high-level signal or a low-level signal. A period of the data signals 150-153 is approximately four times a period of the scan signals 121-136.

In the present embodiment, although the sub-pixel electrodes arranged in a 3×6 matrix serve as an example for explanation of aspects of the present invention, in practice the numbers of data lines, scan lines, and sub-pixel electrodes may be selected depending on desired resolutions. In other words, the numbers of the first and second data lines and the first and second scan lines may be determined according to different design requirements. The M-th scan signal does not overlap the (M+1)-th scan signal in the timing sequence, where M is a positive integer.

After a period of time, the first and the second data lines D1-D4 will complete the charging process of the corresponding sub-pixels. Therefore, by connecting the first sub-pixel electrode P1 to the first switch TFT1 and the to second switch TFT2 and connecting the second sub-pixel electrode P2 and the third sub-pixel electrode P3 to the third switch TFT3 and the fourth switch TFT4 respectively, the first sub-pixel electrode P1 is charged twice as many times as the second sub-pixel electrode P2 or the third sub-pixel electrode P3 is charged. As a result, the problem of line defects caused by insufficient charging efficiency in the initial charging process of an HSD design is resolved.

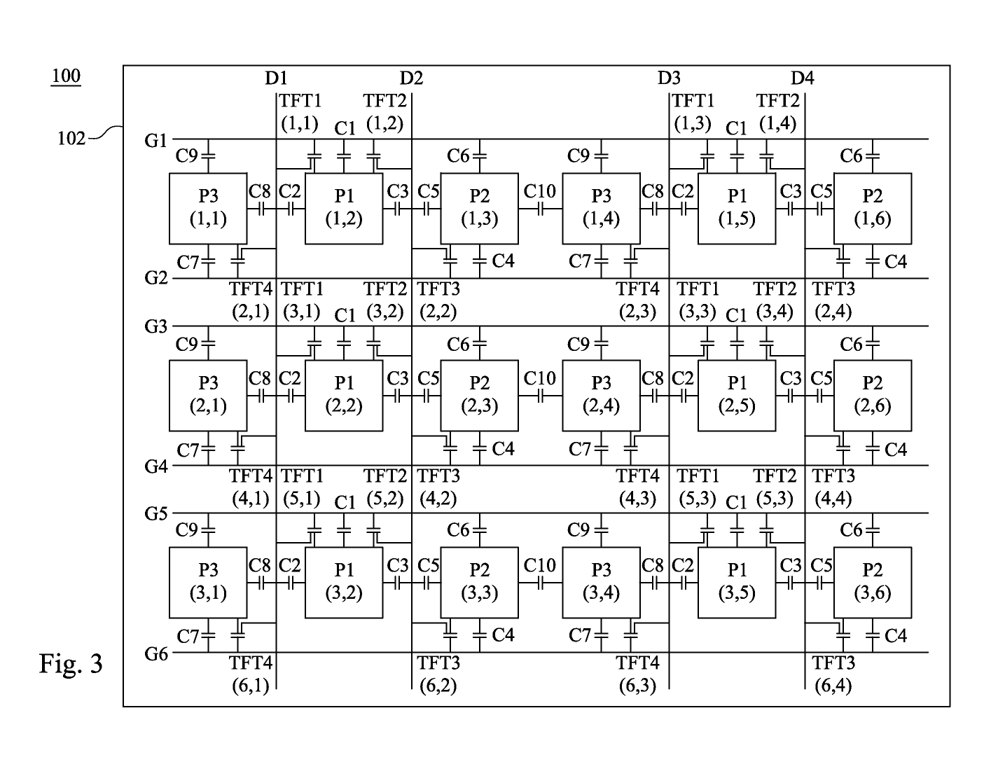

FIG. 3 is a schematic diagram showing a partial top view of the active array substrate 100 according to another embodiment of the present invention. The active array substrate 100 comprises the substrate 102, the plurality of first data lines D1, D3, the plurality of second data lines D2, D4 alternately arranged with the plurality of first data lines D1, D3, the plurality of first scan lines G1, G3, G5, the plurality of second scan lines G2, G4, G6 alternately arranged with the plurality of first scan lines G1, G3, G5, and the plurality of first sub-pixel electrodes P1, the plurality of second sub-pixel electrodes P2, and the third sub-pixel electrodes P3. The data lines D1, D2, D3, D4 are arranged in sequence. The scan lines G1, G2, G3, G4, G5, G6 are arranged in sequence.

More specifically, each of the sub-pixel electrodes in the sub-pixel electrode matrix is represented by PM(i,j) which denotes the M-th sub-pixel electrode in the ith row and the jth column of the sub-pixel electrode matrix. For example, P3(1,1) in the top left corner of the figure denotes the third sub-pixel electrode P3 in the first row and the first column of the sub-pixel electrode matrix, P2(1,6) in the top right corner of the figure denotes the second sub-pixel electrode P2 in the first row and the sixth column of the sub-pixel electrode matrix, and so forth.

The active array substrate 100 further comprises the plurality of first switches TFT1, the plurality of second switches TFT2, and the plurality of third switches TFT3. Each of the first switches TFT1 is connected to the corresponding first sub-pixel electrode P1, the first data line D1 or D3, and the first scan line G1 or G3 or G5. Each of the second switches TFT2 is connected to the corresponding first sub-pixel electrode P1, the second data line D2, D4, and the first scan line G1, G3, G5. Each of the third switches TFT3 is connected to the corresponding second sub-pixel electrode P2, the second data line D2 or D4, and the second scan line G2 or G4 or G6. Each of the fourth switches TFT4 is connected to the corresponding third sub-pixel electrode P3, the first data line D1 or D3, and the second scan line G2 or G4 or G6.

More specifically, the switches can be represented by TFT N (h,k) which denotes the N-th TFT connected to the scan line Gh and the data line Dk. For example, TFT1 (1,1) in the top left corner of the figure denotes the first switch TFT1 connected to the first scan line G1 and the first data line D1, TFT3 (6,4) in the lower right corner of the figure denotes the third switch TFT3 connected to the second scan line G6 and the second data line D4, and so forth.

The active array substrate 100 further comprises a plurality of first capacitors C1. Each of the first capacitors C1 is formed between the corresponding first sub-pixel electrode P1 and the first scan line G1 or G3 or G5. That is, each of the first capacitors C1 is formed between the first sub-pixel electrode P1 and the first scan line G1 (or G3, G5) adjacent to the first sub-pixel electrode P1. For example, the first capacitor C1 is formed between the first sub-pixel electrode P1(1,2) and the first scan line G1 adjacent to the first sub-pixel electrode P1(1,2).

The active array substrate 100 further comprises a plurality of second capacitors C2. Each of the second capacitors C2 is formed between the corresponding first sub-pixel electrode P1 and the first data line D1 or D3. That is, each of the second capacitors C2 is formed between the first sub-pixel electrode P1 and the first data line D1 (or D3) adjacent to the first sub-pixel electrode P1. For example, the second capacitor C2 is formed between the first sub-pixel electrode P1(1,2) and the first data line D1 adjacent to the first sub-pixel electrode P1(1,2).

The active array substrate 100 further comprises a plurality of third capacitors C3. Each of the third capacitors C3 is formed between the corresponding first sub-pixel electrode P1 and the second data line D2 or D4. That is, each of the third capacitors C3 is formed between the first sub-pixel electrode P1 and the second scan line D2 (or D4) adjacent to the first sub-pixel electrode P1. For example, the third capacitor C3 is formed between the first sub-pixel electrode P1(1,2) and the second scan line D2 adjacent to the first sub-pixel electrode P1(1,2).

The active array substrate 100 further comprises a plurality of fourth capacitors C4. Each of the fourth capacitors C4 is formed between the corresponding second sub-pixel electrode P2 and the second scan line G2 or G4 or G6. That is, each of the fourth capacitors C4 is formed between the second sub-pixel electrode P2 and the second scan line G2 (or G4, G6) adjacent to the second sub-pixel electrode P2. For example, the fourth capacitor C4 is formed between the second sub-pixel electrode P2(1,3) and the to second scan line G2 adjacent to the second sub-pixel electrode P2(1,3).

The active array substrate 100 further comprises a plurality of fifth capacitors C5. Each of the fifth capacitors C5 is formed between the corresponding second sub-pixel electrode P2 and the second data line D2 or D4. That is, each of the fifth capacitors C5 is formed between the second sub-pixel electrode P2 and the data line arranged in front of the second sub-pixel electrode P2.

The active array substrate 100 further comprises a plurality of sixth capacitors C6. Each of the sixth capacitors C6 is formed between the corresponding second sub-pixel electrode P2 and the first scan line G1 or G3 or G5. That is, each of the sixth capacitors C6 is formed between the second sub-pixel electrode P2 and the first scan line G1 (or G3, G5) adjacent to the second sub-pixel electrode P2. For example, the sixth capacitor C6 is formed between the second sub-pixel electrode P2(1,3) and the first scan line G1 adjacent to the second sub-pixel electrode P2(1,3).

The active array substrate 100 further comprises a plurality of seventh capacitors C7. Each of the seventh capacitors C7 is formed between the corresponding third sub-pixel electrode P3 and the second scan line G2 or G4 or G6. That is, each of the seventh capacitors C7 is formed between the third sub-pixel electrode P3 and the second scan line G2 (or G4, G6) adjacent to the third sub-pixel electrode P3. For example, the seventh capacitor C7 is formed between the third sub-pixel electrode P3(1,4) and the second scan line G2 adjacent to the third sub-pixel electrode P3(1,4).

The active array substrate 100 further comprises a plurality of eighth capacitors C8. Each of the eighth capacitors C8 is formed between the corresponding third sub-pixel electrode P3 and the first data line D1 or D3. That is, each of the eighth capacitors C8 is formed between the third sub-pixel electrode P3 and the first scan line D1 (or D3) adjacent to the third sub-pixel electrode P3. For example, the eighth capacitor C8 is formed between the third sub-pixel electrode P3(1,4) and the first data line D3 adjacent to the third sub-pixel electrode P3(1,4).

The active array substrate 100 further comprises a plurality of ninth capacitors C9. Each of the ninth capacitors C9 is formed between the corresponding third sub-pixel electrode P3 and the first scan lines G1 or G3 or G5. That is, each of the ninth capacitors C9 is formed between the third sub-pixel electrode P3 and the first scan line G1 (or G3, G5) adjacent to the third sub-pixel electrode P3. For example, the ninth capacitor C9 is formed between the third sub-pixel electrode P3(1,4) and the first scan line G1 adjacent to the third sub-pixel electrode P3(1,4).

The active array substrate 100 further comprises a plurality of tenth capacitors C10. Each of the tenth capacitors C10 is formed between the corresponding second sub-pixel electrode P2 and the third sub-pixel electrode P3 adjacent to the corresponding second sub-pixel electrode P2. For example, the tenth capacitor C10 is formed between the third sub-pixel electrode P3(1,4) and the second sub-pixel electrode P2 (1,3) adjacent to the third sub-pixel electrode P3(1,4).

In the present embodiment, except for the outmost columns located at either side of the active array substrate 100, each of the first sub-pixel electrodes P1 is connected to the same amount of capacitance, each of the second sub-pixel electrodes P2 is connected to the same amount of capacitance, and each of the third sub-pixel electrodes P3 is connected to the same amount of capacitance. That is, the sub-pixel electrodes of the same color are connected to approximately the same amount of capacitance. Hence, the line defect problem caused by an imbalance in parasitic capacitances is resolved. Specifically, each of the first sub-pixel electrodes P1 is connected to the first to the third capacitors C1-03, each of the second sub-pixel electrodes P2 is connected to the fourth to the sixth capacitors C4-C6, and each of the third sub-pixel electrodes P3 is connected to the seventh to the ninth capacitors C7-C9. The tenth capacitor C10 is further disposed between the second sub-pixel electrode P2 and the third sub-pixel electrode P3 adjacent to the second sub-pixel electrode P2.

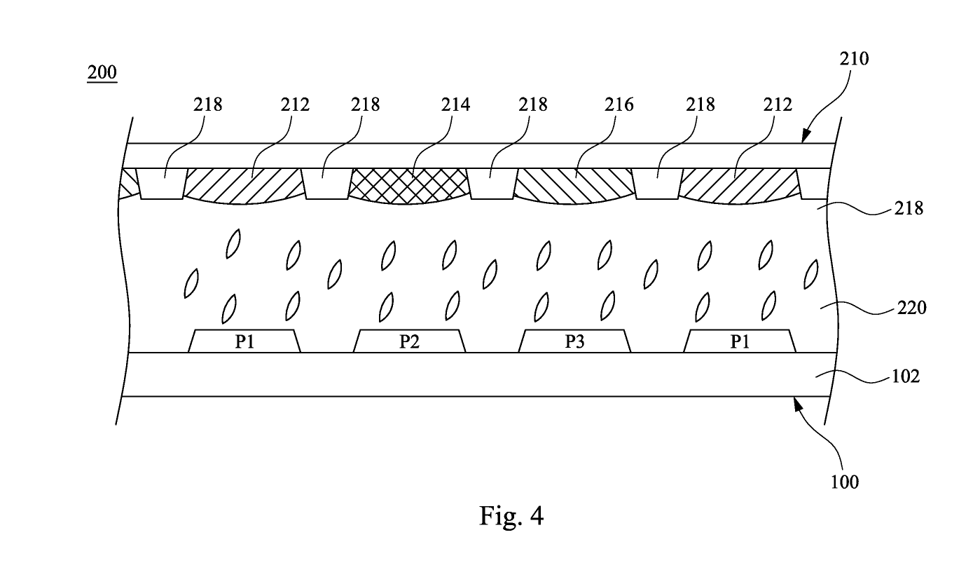

FIG. 4 is a schematic diagram showing a cross-sectional view of a liquid crystal panel using the active array substrate 100 according to an embodiment of the present invention. The liquid crystal display panel 200 comprises the above-mentioned active array substrate 100, an opposite substrate 210, and a liquid crystal layer 220 disposed between the active array substrate 100 and the opposite substrate 220. It is noted that only the substrate 102 and the sub-pixel electrodes P1, P2, P3 on the substrate 102 of the active array substrate 100 are depicted in the figure for describing the liquid crystal panel. Reference may be made to FIG. 1 or FIG. 3 for the detailed structure of the active array substrate 100.

The opposite substrate 210 may be a color filter that comprises a plurality of first primary-color filter layers 212, a plurality of second primary-color filter layers 214, and a plurality of third primary-color filter layers 216. Each of the first primary-color filter layers 212 overlaps one of the first sub-pixel electrodes P1, each of the second primary-color filter layers 214 overlaps one of the second sub-pixel electrodes P2, and each of the third primary-color filter layers 216 overlaps one of the third sub-pixel electrodes P3. The first primary-color filter layers 212, the second primary-color filter layers 214, and the third primary-color filter layers 216 are color filter layers of three primary colors, namely red, blue, and green. If the first primary-color filter layers 212 are red color filter layers, the second primary-color filter layers 214 and the third primary-color filter layers 216 are blue color filter layers and green color filter layers respectively, or green color filter layers and blue color filter layers respectively. If the first primary-color filter layers 212 are green color filter layers, the second primary-color filter layers 214 and the third primary-color filter layers 216 are blue color filter layers and red color filter layers respectively, or red color filter layers and blue color filter layers respectively. If the first primary-color filter layers 212 are blue color filter layers, the second primary-color filter layers 214 and the third primary-color filter layers 216 are red color filter layers and green color filter layers respectively, or green color filter layers and red color filter layers respectively. The first primary-color filter layers 212, the second primary-color filter layers 214, and the third primary-color filter layers 216 can be isolated by a black matrix 218.

Hence, each of the sub-pixel electrodes of the same color in the liquid crystal display panel 200 is connected to the capacitors having the same magnitude of total capacitance (except for the outmost columns located at either side of the active array substrate). As a result, the parasitic to capacitances between the pixels are balanced.

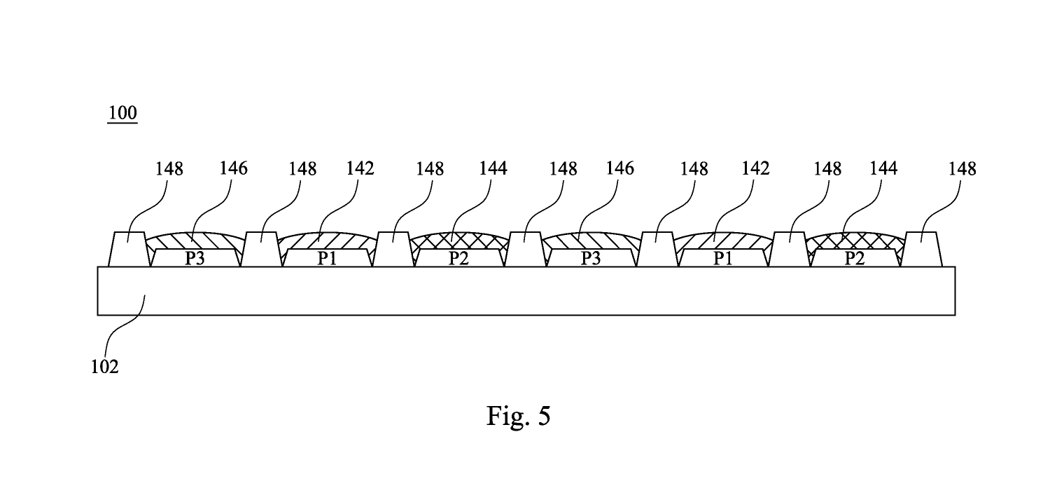

FIG. 5 is a schematic diagram showing a partial cross-sectional view of the active array substrate 100 according to a further embodiment of the present invention. In the present embodiment, the active array substrate 100 may be a color filter on array (COA) substrate. That is, a color filter and an active array are both formed on the same substrate. The active array substrate 100 differs from that of the above-mentioned embodiment in that the active array substrate 100 further comprises a plurality of first primary-color filter layers 142, a plurality of second primary-color filter layers 144, and a plurality of third primary-color filter layers 146. Each of the first primary-color filter layers 142 overlaps one of the first sub-pixel electrodes P1, each of the second primary-color filter layers 144 overlaps one of the second sub-pixel electrodes P2, and each of the third primary-color filter layers 146 overlaps one of the third sub-pixel electrodes P3. The first primary-color filter layers 142, the second primary-color filter layers 144, and the third primary-color filter layers 146 are color filter layers of three primary colors, namely red, blue, and green. If the first primary-color filter layers 142 are red color filter layers, the second primary-color filter layers 144 and the third primary-color filter layers 146 are blue color filter layers and green color filter layers respectively, or green color filter layers and blue color filter layers respectively. If the first primary-color filter layers 142 are green color filter layers, the second primary-color filter layers 144 and the third primary-color filter layers 146 are blue color filter layers and red color filter layers respectively, or red color filter layers and blue color filter layers respectively. If the first primary-color filter layers 142 are blue color filter layers, the second primary-color filter layers 144 and the third primary-color filter layers 146 are red color filter layers and green color filter layers respectively, or green color filter layers and red color filter layers respectively. The first primary-color filter layers 142, the second primary-color filter layers 144, and the third primary-color filter layers 146 can be isolated by a black matrix 148 disposed on the substrate 102 and between the sub-pixel electrodes P1, P2, P3. If the configuration according to the present embodiment is applied to a liquid crystal display panel, it is not necessary to dispose color filter layers on the corresponding opposite substrate.

Hence, each of the sub-pixel electrodes of the same color in the liquid crystal display panel using the active array substrate 100 is connected to the capacitors having the same magnitude of total capacitance (except for the outmost columns located at either side of the active array substrate). As a result, the parasitic capacitances between the pixels are balanced.

In summary, the present invention provides a design of the active array substrate to effectively resolve the line defect problem caused by inconsistent charging efficiencies or imbalanced capacitances in the traditional design of an HSD.

Although the present invention has been described in considerable detail with reference to certain embodiments thereof, other embodiments are possible. Therefore, the spirit and scope of the appended claims should not be limited to the description of the embodiments contained herein.

It will be apparent to those skilled in the art that various modifications and variations can be made to the structure of the present invention without departing from the scope or spirit of the invention. In view of the foregoing, it is to intended that the present invention cover modifications and variations of this invention provided they fall within the scope of the following claims.

What is claimed is:

1. An active array substrate, comprising:
a substrate;
a plurality of first scan lines and a plurality of second scan lines alternately disposed on the substrate;
a plurality of first data lines and a plurality of second data lines alternately disposed on the substrate, the plurality of first scan lines and the plurality of second scan lines crossing the plurality of first data lines and the plurality of second data lines;
a plurality of first sub-pixel electrodes;
a plurality of second sub-pixel electrodes, each of the second sub-pixel electrodes and one of the first sub-pixel electrodes being located at opposite sides of one of the second data lines;
a plurality of third sub-pixel electrodes, each of the third sub-pixel electrodes corresponding to one of the first sub-pixel electrodes, and the each of the third sub-pixel electrodes and the corresponding first sub-pixel electrode being located at opposite sides of one of the first data lines;
a plurality of first switches, each of the first switches being connected to one of the first sub-pixel electrodes, one of the first data lines, and one of the first scan lines;
a plurality of second switches, each of the second switches being connected to one of the first sub-pixel electrodes, one of the second data lines, and one of the first scan lines;
a plurality of third switches, each of the third switches being connected to one of the second sub-pixel electrodes, one of the second data lines, and one of the second scan lines; and
a plurality of fourth switches, each of the fourth switches being connected to one of the third sub-pixel electrodes, one of the first data lines, and one of the second scan lines.

2. The active array substrate of claim 1, further comprising:
a plurality of red color filter layers, each of the red color filter layers to overlapping one of the first sub-pixel electrodes;
a plurality of green color filter layers, each of the green color filter layers overlapping one of the second sub-pixel electrodes; and
a plurality of blue color filter layers, each of the blue color filter layers overlapping one of the third sub-pixel electrodes.

3. The active array substrate of claim 1, further comprising:
a plurality of green color filter layers, each of the green color filter layers overlapping one of the first sub-pixel electrodes;
a plurality of red color filter layers, each of the red color filter layers overlapping one of the second sub-pixel electrodes; and
a plurality of blue color filter layers, each of the blue color filter layers overlapping one of the third sub-pixel electrodes.

4. The active array substrate of claim 1, further comprising:
a plurality of blue color filter layers, each of the blue color filter layers overlapping one of the first sub-pixel electrodes;
a plurality of green color filter layers, each of the green color filter layers overlapping one of the second sub-pixel electrodes; and
a plurality of red color filter layers, each of the red color filter layers overlapping one of the third sub-pixel electrodes.

5. The active array substrate of claim 1, wherein each of the second sub-pixel electrodes and the third sub-pixel electrode adjacent to the each of the second sub-pixel electrodes are located between one of the second data lines and one of the first data lines adjacent to the one of the second data lines.

6. A liquid crystal display panel, comprising:
an active array substrate, the active array substrate comprising:
a substrate;
a plurality of first scan lines and a plurality of second scan lines alternately disposed on the substrate;
a plurality of first data lines and a plurality of second data lines alternately disposed on the substrate, the plurality of first scan lines and the plurality of second scan lines crossing the plurality of first data lines and the plurality of second data lines;
a plurality of first sub-pixel electrodes;
a plurality of second sub-pixel electrodes, each of the second sub-pixel electrodes and one of the first sub-pixel electrodes being located at opposite sides of one of the second data lines;
a plurality of third sub-pixel electrodes, each of the third sub-pixel electrodes corresponding to one of the first sub-pixel electrodes, the each of the third sub-pixel electrodes and the corresponding first sub-pixel electrode being located at opposite sides of one of the first data lines;
a plurality of first switches, each of the first switches being connected to one of the first sub-pixel electrodes, one of the first data lines, and one of the first scan lines;
a plurality of second switches, each of the second switches being connected to one of the first sub-pixel electrodes, one of the second data lines, and one of the first scan lines;
a plurality of third switches, each of the third switches being connected to one of the second sub-pixel electrodes, one of the second data lines, and one of the second scan lines; and
a plurality of fourth switches, each of the fourth switches being connected to one of the third sub-pixel electrodes, one of the first data lines, and one of the second scan lines;
an opposite substrate; and
a liquid crystal layer disposed between the active array substrate and the opposite substrate.

7. The liquid crystal display panel of claim 6, wherein the opposite substrate comprises:
a plurality of red color filter layers, each of the red color filter layers overlapping one of the first sub-pixel electrodes;
a plurality of green color filter layers, each of the green color filter layers overlapping one of the second sub-pixel electrodes; and
a plurality of blue color filter layers, each of the blue color filter layers overlapping one of the third sub-pixel electrodes.

8. The liquid crystal display panel of claim 6, wherein the opposite substrate comprises:
a plurality of green color filter layers, each of the green color filter layers overlapping one of the first sub-pixel electrodes;
a plurality of red color filter layers, each of the red color filter layers overlapping one of the second sub-pixel electrodes; and
a plurality of blue color filter layers, each of the blue color filter layers overlapping one of the third sub-pixel electrodes.

9. The liquid crystal display panel of claim 6, wherein the opposite substrate comprises:
a plurality of blue color filter layers, each of the blue color filter layers overlapping one of the first sub-pixel electrodes;
a plurality of green color filter layers, each of the green color filter layers overlapping one of the second sub-pixel electrodes; and
a plurality of red color filter layers, each of the red color filter layers overlapping one of the third sub-pixel electrodes.

10. The liquid crystal display panel of claim 6, wherein the active array substrate comprises:
a plurality of red color filter layers, each of the red color filter layers overlapping one of the first sub-pixel electrodes;
a plurality of green color filter layers, each of the green color filter layers overlapping one of the second sub-pixel electrodes; and
a plurality of blue color filter layers, each of the blue color filter layers overlapping one of the third sub-pixel electrodes.

11. The liquid crystal display panel of claim 6, wherein the active array substrate comprises:
a plurality of green color filter layers, each of the green color filter layers overlapping one of the first sub-pixel electrodes;
a plurality of red color filter layers, each of the red color filter layers overlapping one of the second sub-pixel electrodes; and
a plurality of blue color filter layers, each of the blue color filter layers overlapping one of the third sub-pixel electrodes.

12. The liquid crystal display panel of claim 6, wherein the active array substrate comprises:
a plurality of blue color filter layers, each of the blue color filter layers overlapping one of the first sub-pixel electrodes;
a plurality of green color filter layers, each of the green color filter layers overlapping one of the second sub-pixel electrodes; and
a plurality of red color filter layers, each of the red color filter layers overlapping one of the third sub-pixel electrodes.

13. The liquid crystal display panel of claim 6, wherein each of the second sub-pixel electrodes and the third sub-pixel electrode adjacent to the each of the second sub-pixel electrodes are located between one of the second data lines and one of the first data lines adjacent to the one of the second data lines.

14. A driving method for the active array substrate of claim 1, comprising:
providing a plurality of scan signals to the plurality of first scan lines and the plurality of second scan lines alternately arranged with the plurality of first scan lines sequentially, the M-th scan signal not overlapping the (M+1)-th scan signal in timing sequence, and M being a positive integer; and
providing a plurality of data signals to the plurality of first data lines and the plurality of second data lines alternately arranged with the plurality of first data lines sequentially.

15. The driving method of claim 14, wherein each of the data signals comprises a high-level signal or a low-level signal.

16. The driving method of claim 14, wherein a period of the data signals is approximately four times of a period of the scan signals.
